(19) United States
(12) Patent Application Publication
(10) Pub. No.: US 2025/0040230 A1
(43) Pub. Date: Jan. 30, 2025

(54) SEMICONDUCTOR DEVICE AND MANUFACTURING METHOD OF SEMICONDUCTOR DEVICE

(71) Applicant: Silergy Semiconductor Technology (Hangzhou) LTD, Hangzhou (CN)

(72) Inventors: Jiajun Chen, Hangzhou (CN); Song Pu, Hangzhou (CN); Fabei Zhang, Hangzhou (CN); Shilin Cao, Hangzhou (CN); Hui Yu, Hangzhou (CN); Jun Cai, Hangzhou (CN)

(21) Appl. No.: 18/775,869

(22) Filed: Jul. 17, 2024

(30) Foreign Application Priority Data
Jul. 28, 2023 (CN) 202310943421.7

(51) Int. Cl. H01L 29/49; H01L 21/265; H01L 21/266; H01L 21/3215; H01L 29/06; H01L 29/66; H01L 29/78

(52) U.S. Cl. CPC H01L 29/4983; H01L 29/0653; H01L 29/66681; H01L 29/7816

(57) ABSTRACT

A semiconductor device can include: a substrate; a well region located in the substrate and having a first doping type; a body region located in the substrate and having a second doping type that is opposite to the first doping type; a source region located in the body region and having the first doping type; a drain region located in the well region and having the first doping type; an isolation structure located on the substrate and between the drain region and the source region; and a gate structure located on the isolation structure and including a first gate region and a second gate region, where the first gate region is of the first doping type, and the second gate region is of the second doping type.

### RELATED APPLICATIONS

This application claims the benefit of Chinese Patent Application No. 202310943421.7, filed on Jul. 28, 2023, which is incorporated herein by reference in its entirety.

### FIELD OF THE INVENTION

The present invention generally relates to the field of semiconductor technology, and more particularly to semiconductor devices and associated manufacturing methods.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1A is a cross-sectional view of a first example semiconductor device, in accordance with embodiments of the present invention.

FIG. 1B is a cross-sectional view of a second example semiconductor device, in accordance with embodiments of the present invention.

FIG. 2 is a cross-sectional view of a third example semiconductor device, in accordance with embodiments of the present invention.

FIG. 3 is a cross-sectional view of a fourth example semiconductor device, in accordance with embodiments of the present invention.

FIG. 4 is a flow diagram of an example manufacturing method of semiconductor devices, in accordance with embodiments of the present invention.

FIG. 5 is a flow diagram of an example manufacturing method of a first isolation structure, in accordance with embodiments of the present invention.

FIGS. 6A-6F are cross-sectional views of various stages of an example manufacturing method of semiconductor devices, in accordance with embodiments of the present invention.

FIG. 7 is a flow diagram of an example manufacturing method of a second example isolation structure, in accordance with embodiments of the present invention.

FIG. 8 is a cross-sectional view of a second example isolation structure, in accordance with embodiments of the present invention.

FIGS. 9A and 9B are flow diagrams of an example manufacturing method of the second example isolation structure, in accordance with embodiments of the present invention.

FIG. 10A is a cross-sectional view of example formation of a front gate region, in accordance with embodiments of the present invention.

FIG. 10B is a cross-sectional view of an example formation of a first gate region, a source region, and a drain region, in accordance with embodiments of the present invention.

FIG. 10C is a cross-sectional view of an example formation of a second gate region and a body contact region, in accordance with embodiments of the present invention.

FIG. 10D is a cross-sectional view of an example formation of a source electrode and a drain electrode, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

BCD devices include bipolar junction transistors (BJT), complementary metal-oxide-semiconductor (CMOS), and double-diffused metal-oxide-semiconductor (DMOS). BJT can be used for processing analog signals, CMOS for controlling digital signals, and DMOS for drivers with high voltage or high power output. Therefore, BCD devices may have advantages of high transconductance, high voltage resistance, good noise resistance, high integration, and low power consumption by combining the performance of BJT, CMOS, and DMOS.

High voltage N-type metal oxide semiconductor transistors typically use N-type doped polysilicon as the gate to lower the device threshold and ensure sufficient gate driving capability. When the gate oxide layer is very thin, the accumulation region may form an electric field with the drift region under the high voltage difference between the drain and the gate, which can lead to severe hot carrier effects. The current performance of the device may gradually deteriorate with time, and the reliability can be challenged. In high-frequency applications, switch losses may gradually dominate, and the drain-gate capacitance value can be the dominant factor affecting switch losses. The drain-gate capacitance value can mainly be determined by the thickness of the oxide layer between the drain and the gate, and the design of the thickness of the oxide layer may be limited by the balance between breakdown voltage and conduction resistance, and cannot be arbitrarily changed. Therefore, N-type doped polysilicon gate may not form a depletion layer under the high voltage difference between the drain and the gate, so the drain-gate capacitance is usually large and the switching loss is high.

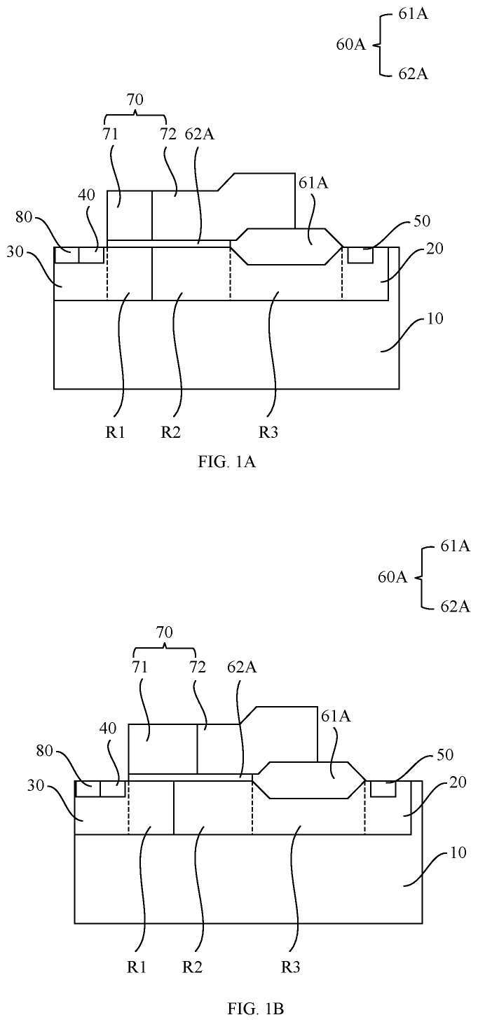

Referring now to FIG. 1A, shown is a cross-sectional view of a first example semiconductor device, in accordance with embodiments of the present invention. In this particular example, the semiconductor device can include substrate 10, well region 20, body region 30, source region 40, drain region 50, isolation structure 60A, and gate structure 70. Well region 20 can be located in the substrate 10 and may be of a first doping type. Body region 30 can be located in substrate 10 and may be of a second doping type. Body region 30 may be adjacent to well region 20, whereby the second doping type is opposite to the first doping type. Source region 40 can be located in body region 30 and may be of the first doping type. Drain region 50 can be located in well region 20 and may be of the first doping type. Isolation structure 60A can be located on substrate 10, and may extend from drain region 50 to source region 40. Gate structure 70 can be located on isolation structure 60A, and may include adjacent gate region 71 and gate region 72. Gate region 71 may be of the first doping type, and gate region 72 of the second doping type.

In one embodiment, the doping type of substrate 10 can be the same as that of body region 30, and body region 30 may be in contact with well region 20. When the doping type of substrate 10 is the same as that of well region 20, and body region 30 and well region 20 may be in contact or may not be in contact. The material of substrate 10 can include silicon, which can be a first doping type or a second doping type. For example, the first doping type is one of N-type and P-type, and the second doping type is the other of N-type and P-type. N-type dopants can be implanted into substrate 10 to form an N-type semiconductor layer or region, and the N-type dopants can be phosphorus (P) or arsenic (As). P-type dopants can be implanted into substrate 10 to form a P-type semiconductor layer or region, whereby the P-type dopants can be boron (B). In this example, the first doping type is N-type, and the second doping type is P-type.

In one embodiment, the semiconductor device can be configured as an N-type laterally diffused metal oxide semiconductor (LDMOS) transistor, including N-type well region 20, N-type source region 40, N-type drain region 50, and P-type body region 30. In another example, the semiconductor device can be configured as a P-type LDMOS, including P-type well region 20, P-type source region 40, P-type drain region 50, and N-type body region 30.

For example, well region 20 may extend from a top surface of substrate 10 to interior of substrate 10 to block the holes of substrate 10 and surround drain region 50. Body region 30 may extend from the top surface of substrate 10 to interior of substrate 10. A length of body region 30 can be less than that of well region 20. A part of body region 30 may be located below gate structure 70, and may provide an inversion channel for the semiconductor device during conduction operation, whereby the inversion channel is a channel of the semiconductor device. After the formation of well region 20 and body region 30, source region 40 may extend from the top surface of substrate 10 to body region 30 to the interior of body region 30, while drain region 50 may extend from the top surface of substrate 10 to the interior of well region 20.

Isolation structure 60A can include oxide layers 61A and 62A, where oxide layer 61A can be a local oxidation of silicon (LOCOS) structure. By configuring isolation structure 60A, gate structure 70 can be protected from current breakdown, and electrons may be prevented from transferring into gate structure 70. Oxide layer 61A can be located on an upper surface of well region 20, and a first side of oxide layer 61A may be adjacent to drain region 50. Oxide layer 61A can protrude relative to the top surface of substrate 10, and may extend towards an interior of well region 20. Further, a part of oxide layer 61A near drain region 50 may not be covered by gate region 72, while the remaining part of oxide layer 61A can be covered by gate region 72. Oxide layer 62A can at least be located on the top surface of substrate 10 between a second side of oxide layer 61A and source region 40, and may extend to source region 40. That is, oxide layer 62A can cover the top surface of a part of well region 20 and a part of body region 30, and may serve as a gate oxide layer. For example, the first side of oxide layer 61A is opposite to the second side of oxide layer 61A.

Gate region 71 can at least be located on isolation structure 60A located above body region 30. Further, gate region 71 can be located on oxide layer 62A above body region 30 and in contact with oxide layer 62A. Gate region 71 can be heavily doped N-type polysilicon. Gate region 72 may be located on isolation structure 60A above well region 20. In addition, gate region 72 can be located on oxide layers 61A and 62A, and may be in contact with oxide layers 61A and 62A. Gate region 72 can be lightly doped P-type polysilicon, moderately doped P-type polysilicon, or heavily doped P-type polysilicon. Further, the projection of gate region 71 on substrate 10 and the projection of gate region 72 on substrate 10 may both be located between source region 40 and drain region 50. The length of the projection of gate region 71 on substrate 10 can be smaller than that of the projection of gate region 72 on substrate 10. The doping type of gate region 71 may be opposite to that of gate region 72. Due to the protrusion of oxide layer 61A, a side where gate region 72 contacts oxide layer 61A can be higher than a side where gate region 71 contacts oxide layer 62A.

In this embodiment, the semiconductor device can also include body contact region 80. Body contact region 80 can be located in body region 30 and adjacent to source region 40. Further, body contact region 80 may extend from the top surface of substrate 10 to interior of body region 30. Body contact region 80 can be located on one side of source region 40 relative to gate structure 70 and away from gate structure 70. Body contact region 80 may be a doping region mainly composed of silicon, and can be the second doping type (e.g., a P-type doped region).

The region between source region 40 and drain region 50 can be divided into three parts: channel region R1, accumulation region R2, and drift region R3. Channel region R1 can be located on a side near source region 40, drift region R3 may be located on a side near drain region 50, and accumulation region R2 can be located between channel region R1 and drift region R3. For example, channel region R1 can be located in body region 30 below gate structure 70, and drift region R3 may be located in well region 20 below isolation structure 60A. in addition, body region 30 located directly below gate oxide layer can be set as channel region R1, well region 20 located directly below oxide layer 61A may be set as drift region R3, and well region 20 located between channel region R1 and drift region R3 can be set as accumulation region R2. Oxide layer 61A can be located on the drift region R3, and oxide layer 62A being in contact with the gate structure 70 may be located on channel region R1 and accumulation region R2.

In one embodiment, as shown in FIG. 1A, gate region 71 can be located on channel region R1, and gate region 72 may be located on drift region R3 and accumulation region R2. In another embodiment, as shown in FIG. 1B, gate region 71 can be located on channel region R1 and part of accumulation region R2, and gate region 72 may be located on drift region R3 and part of accumulation region R2. By configuring gate region 71 on channel region R1, the threshold voltage of the semiconductor device can be reduced and the gate driving capability improved.

Well region 20, body region 30, source region 40, and drain region 50 can be doped regions mainly composed of silicon, and N-type or P-type dopants can be selected based on the doping types of well region 20, body region 30, source region 40, and drain region 50. The materials of oxide layers 61A and 62A may include, e.g., SiOₓ, SiON, SiOC, AlOₓ, HfO₂, Y₂O₃, Y₂TiO₅, Yb₂O₃, ZrO₂, TiO₂, Ta₂O₅, or their combinations.

When drain electrode corresponding to drain region 50 receives a high voltage, gate structure 70 can generate induced electrons near surface of oxide layers 61A and 62A, and the holes and induced electrons in gate region 72 may form a depletion layer. The function of the depletion layer is as follows. First, due to the configuration of isolation structure 60A and gate region 72, the oxide layer capacitor and the depletion layer capacitor from the drain to the gate can connect in series, resulting in a decrease in the total capacitance value from the drain to the gate. The thinner the thickness of oxide layers 61A and 62A are, the more obvious the capacitance optimization. The switch loss can be positively correlated with the voltage difference of the total capacitance from the drain to the gate, thereby the switch loss may be reduced. Second, during the switching period of semiconductor devices, there can be a high voltage difference between the drain to the gate, which may cause accumulation region R2 to become a high electric field region. The high electric field in accumulation region R2 may cause some electrons to gain additional kinetic energy and enter oxide layer 62A, which can lead to degradation of the threshold voltage and a decrease in current of the semiconductor device.

The high electric field of accumulation region R2 can be formed by the superposition of surface transverse electric field and surface longitudinal electric field. The longitudinal electric field may be related to the thickness of oxide layer 62A and the doping concentration of body region 30. The effect of the capacitance of the depletion layer can be equivalent to thickening the thickness of oxide layer 62A on the surface of the accumulation region, so the drain-gate voltage difference from on the surface of the substrate can become smaller. Based on the voltage being proportional to the electric field, the longitudinal electric field on the surface of accumulation region R2 can decrease, and the possibility of electrons entering oxide layer 62A suppressed, such that the current of the semiconductor device is more stable with time, and the reliability of the semiconductor device is improved.

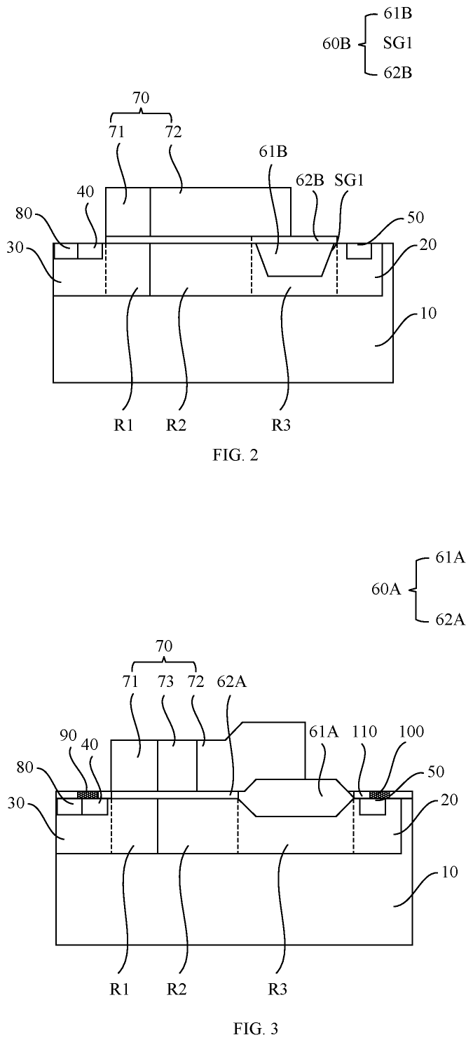

Referring now to FIG. 2, shown is a cross-sectional view of a third example semiconductor device, in accordance with embodiments of the present invention. In this particular example, the semiconductor device can include substrate 10, well region 20, body region 30, source region 40, drain region 50, isolation structure 60B, and gate structure 70. The configuration of substrate 10, well region 20, body region 30, source region 40, drain region 50, and gate structure 70 in FIG. 2 is similar to that shown in FIG. 1A.

As shown in FIG. 2, isolation structure 60B can include shallow trench SG1 filled with insulation layer 61B and insulation layer 62B. Shallow trench SG1 filled with insulation layer 61B is a shallow trench isolation (STI) structure. Shallow trench SG1 can be located in well region 20, and may extend from the top surface of substrate 10 to interior of well region 20. The projection of gate region 72 on substrate 10 may overlap part of shallow trench SG1. Insulation layer 62B can at least be located between shallow trench SG1 and source region 40. For example, insulation layer 62B can be located on the surface of substrate 10 between shallow trench SG1 and source region 40, and may cover shallow trench SG1, part of body region 30, and part of well regions 20. By configuring isolation structure 60B, the leakage current of the semiconductor devices can be prevented, and electrical isolation achieved. It should be noted that due to the flat surface of insulation layer 62B, the surface of the gate structure 70 can also be flat.

Correspondingly, due to the different configuration of isolation structure 60B and isolation structure 60A, the positions of channel region R1, accumulation region R2, and drift region R3 may also change accordingly. For example, body region 30 located directly below insulation layer 62B can be set as channel region R1, well region 20 located directly below shallow trench SG1 set as drift region R3, and well region 20 located between channel region R1 and drift region R3 set as accumulation region R2. The materials of insulation layer 61B and insulation layer 62B may include, e.g., SiOₓ, SiON, SiOC, AlOₓ, HfO₂, SiNₓ, SiCBN, SiCN, SiOCN, Y₂O₃, Y₂TiO₅, Yb₂O₃, ZrO₂, TiO₂, Ta₂O₅, or their combinations.

Referring now to FIG. 3, shown is a cross-sectional view of a fourth example semiconductor device, in accordance with embodiments of the present invention. In this particular example, the semiconductor device can include substrate 10, well region 20, body region 30, source region 40, drain region 50, isolation structure 60A, gate structure 70, body contact region 80, source electrode 90, drain electrode 100, and dielectric layer 110. Substrate 10, well region 20, body region 30, source region 40, drain region 50, isolation structure 60A are similar in configuration to that shown in FIG. 1A.

Gate structure 70 can include gate region 71, gate region 72, and front gate region 73. The configuration of gate region 71 and gate region 72 shown in FIG. 3 is similar to the configuration of gate region 71 and gate region 72 shown in FIG. 1A. Front gate region 73 can be located between gate region 71 and gate region 72, and located on accumulation region R2. The projection of front gate region 73 on substrate 10 can be between source region 40 and drain region 50. The length of the projection of front gate region 73 on substrate 10 may be smaller than the length of the projection of gate region 71 on substrate 10 and the length of the projection of gate region 72 on substrate 10.

Front gate region 73 can be the first doping type and/or the second doping type (e.g., P-type and/or N-type). For example, when front gate region 73 is the first doping type and the second doping type, a first part of front gate region 73 near gate region 71 can be the first doping type, and a second part of front gate region 73 near second gate region 71 can be the second doping type. When front gate region 73 is the first doping type, the doping type of front gate region 73 can be the same as that of gate region 71, and the doping concentration of front gate region 73 may be lower than that of gate region 71. When front gate region 73 is the second doping type, the doping type of front gate region 73 can be the same as that of gate region 72, and the doping concentration of front gate region 73 may be lower than that of gate region 72.

Source electrode 90 can be located on source region 40. Further, source electrode 90 can contact source region 40 and body contact region 80. Drain electrode 100 may be located on drain region 50. Further, drain electrode 100 can contact drain region 50. The materials of source electrode 90 and drain electrode 100 may include, e.g., TiN, TaN, Al, TiAL, In, Sn, Au, Pt, In, Zn, Ge, Ag, Pb, Pd, Cu, AuBe, BeGe, Ni, PbSn, Cr, AuZn, Ti, W, TiW, or their alloys. Dielectric layer 110 can be located between source electrode 90 and gate region 71, as well as between drain electrode 100 and gate region 72, in order to electrically isolate source electrode 90, drain electrode 100, and gate structure 70 from each other. The materials of dielectric layer 110 may include, e.g., SiOₓ, SiON, SiOC, AlOₓ, HfO₂, SiNₓ, SiCBN, SiCN, SiOCN, Y₂O₃, Y₂TiO₅, Yb₂O₃, ZrO₂, TiO₂, Ta₂O₅, or their combinations.

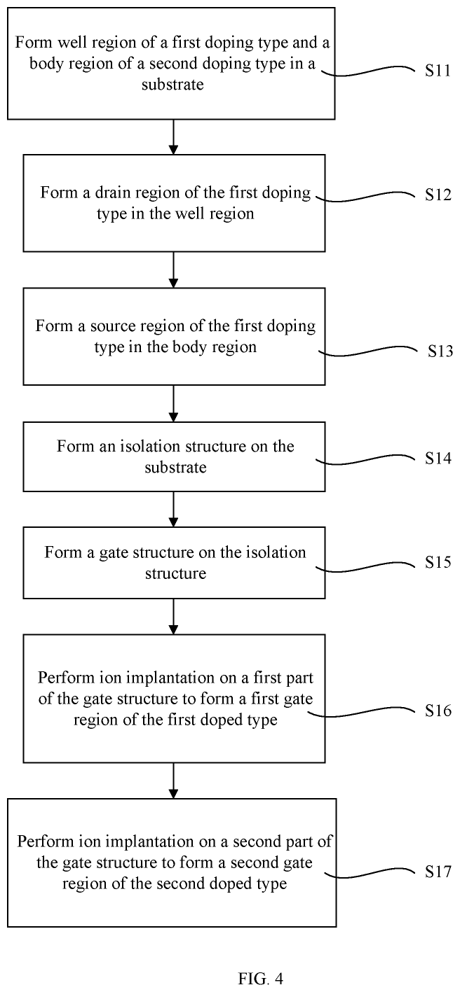

Referring now to FIG. 4, shown is a flow diagram of an example manufacturing method of semiconductor devices, in accordance with embodiments of the present invention. In this particular example, the manufacturing method of semiconductor devices can include steps S11 to S17. This example manufacturing method can be used to form, e.g., the semiconductor devices shown in FIGS. 1A-3. The following example illustrates the manufacturing method here to form the semiconductor device shown in FIG. 1A.

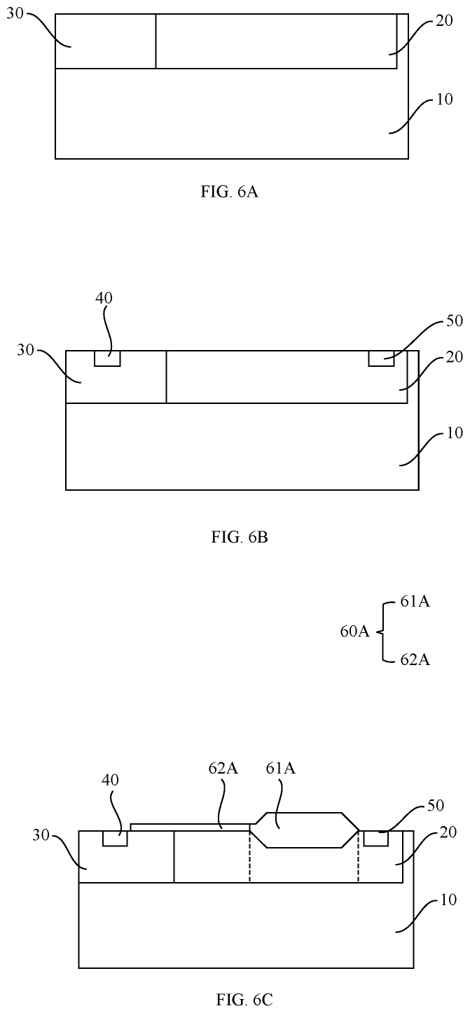

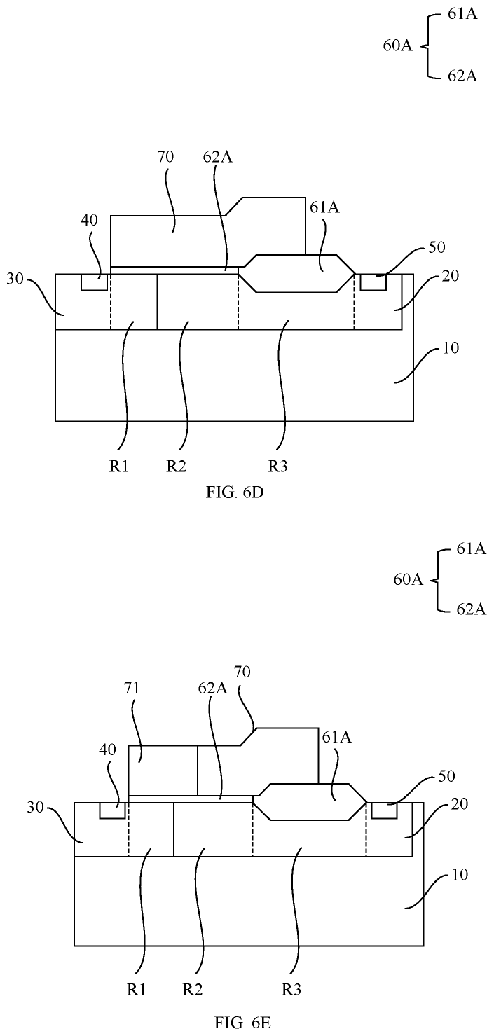

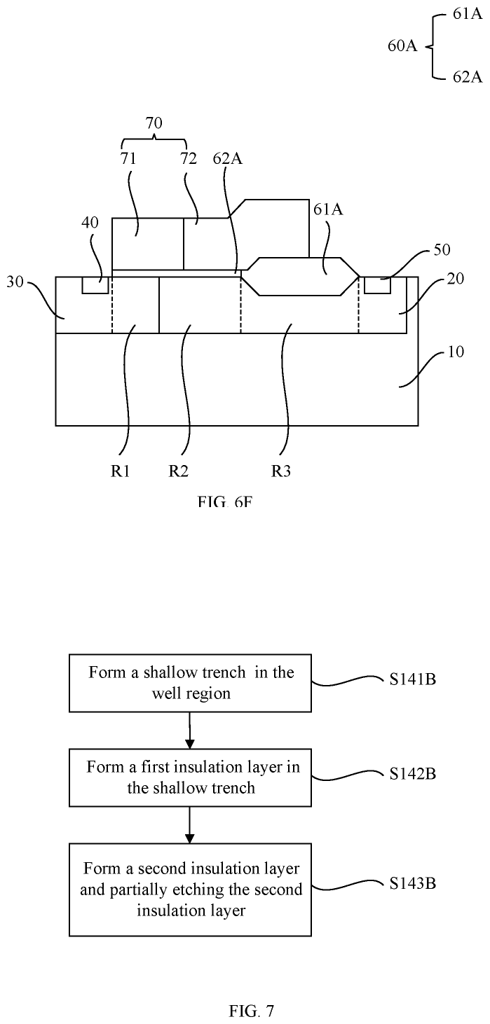

At S11, well region 20 of a first doping type and body region 30 of a second doping type can be formed in substrate 10. As shown in FIG. 6A, well region 20 of the first doping type may formed in substrate 10 by an ion implantation process. Next, body region 30 of the second doped type can be formed in substrate 10, and body region 30 may be adjacent to well region 20.

At S12, drain region 50 of the first doping type can be formed in well region 20. For example, as shown in FIG. 6B, drain region 50 of the first doping type may be formed in well region 20 of the first doping type by an ion implantation process. At S13, source region 40 of the first doping type may be formed in body region 30. For example, as shown in FIG. 6B, source region 40 of the first doping type can be formed in body region 30 of the second doping type by an ion implantation process. For example, steps S12 and S13 can be completed synchronously. At S14, isolation structure 60A or 60B can be formed on substrate 10. In one embodiment, isolation structure 60A may include oxide layers 61A and 62A, where oxide layer 61A is configured as a LOCOS structure. For example, oxide layer 61A can be formed on substrate 10, then oxide layer 62A may be formed on both sides of oxide layer 61A. Also, oxide layer 62A as shown in FIG. 6C can be retained on the surface of the substrate 10 by etching a part of oxide layer 62A. Oxide layer 62A as shown in FIG. 6C can be configured as the gate oxide layer.

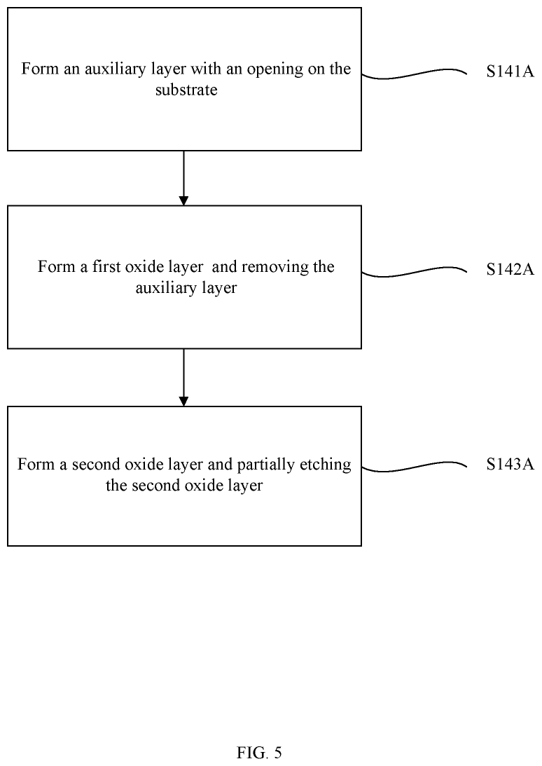

Referring now to FIG. 5, shown is a flow diagram of an example manufacturing method of a first example isolation structure, in accordance with embodiments of the present invention. In this particular example, the steps of forming isolation structure 60A can include steps S141A to S143A. At S141A, an auxiliary layer with an opening can be formed on substrate 10. For example, the auxiliary layer with an opening may be formed on substrate 10, and a part of well region 20 can be exposed by the opening. The material of the auxiliary layer may include, e.g., silicon nitride (SiNₓ). At S142A oxide layer 61A can be formed and the auxiliary layer removed. For example, oxide layer 61A can be formed in the opening by a thermal oxidation process or CVD process. Oxide layer 61A may protrude towards the surface of substrate 10, and extend towards the interior of substrate 10. Then, the auxiliary layer can be removed.

At S143A, oxide layer 62A can be formed and then partially etched. For example, oxide layer 62A can be formed on both sides of oxide layer 61A, and oxide layer 62A may be partially etched by inductively coupled plasma reactive-ion etching (ICP-RIE) or wet etching. Oxide layer 62A as shown in FIG. 6C may remain. The methods for forming oxide layer 62A can be, e.g., CVD, molecular beam epitaxy (MBE), atomic layer deposition (ALD), or sputtering. In another example, isolation structure 60B can include insulation layer 62B and shallow trench SG1 filled with insulation layer 61B, and shallow trench SG1 filled with insulation layer 61B can be configured as an STI structure. For example, shallow trench SG1 can be formed in well region 20, and insulation layer 61B formed in shallow trench SG1, such that insulation layer 61B can be fully filled in shallow trench SG1. Then, insulation layer 62B can be formed to cover well region 20 and body region 30.

Referring now to FIG. 7, shown is a flow diagram of an example manufacturing method of a second example isolation structure, in accordance with embodiments of the present invention. In this particular example, the steps of forming isolation structure 60A may include steps S141B to S143B. At 141B, shallow trench SG1 may be formed in well region 20. For example, a partially etching process can be performed from the top surface of well region 20 to form shallow trench SG1 in well region 20. For example, shallow trench SG1 may extend from the top surface of substrate 10 to the interior of well region 20. In an example, a patterned photoresist layer with an opening can be formed on substrate 10, and dry etching process used to etch the opening from the top surface of substrate 10 to well region 20, in order to form shallow trench SG1. The patterned photoresist layer can then be removed.

In another example, a dielectric layer can be formed on substrate 10, followed by formation of a patterned photoresist layer on the dielectric layer. The dielectric layer can be etched along the direction from an opening of the photoresist layer to the dielectric layer, and stop at the top surface of substrate 10, thereby a penetrating opening in the dielectric layer may be formed. For example, the material of the aforementioned dielectric layer can be the same as that of the auxiliary layer, and the etching process can be ICP-RIE or wet etching. The dielectric layer having the opening can be used as a hard mask, shallow trench SG1 may be formed by etching from the top surface of substrate 10 to well region 20. The photoresist layer and the dielectric layer can then be removed.

At S142B, insulation layer 61B can be formed in shallow trench SG1. For example, insulation layer 61B may be formed on shallow trench SG1 and substrate 10, such that insulation layer 61B is fully filled in shallow trench SG1. Then, insulation layer 61B may be partially etched to remove insulation layer 61B located on substrate 10. The methods for forming insulation layer 61B can, e.g., be CVD, MBE, ALD, or sputtering.

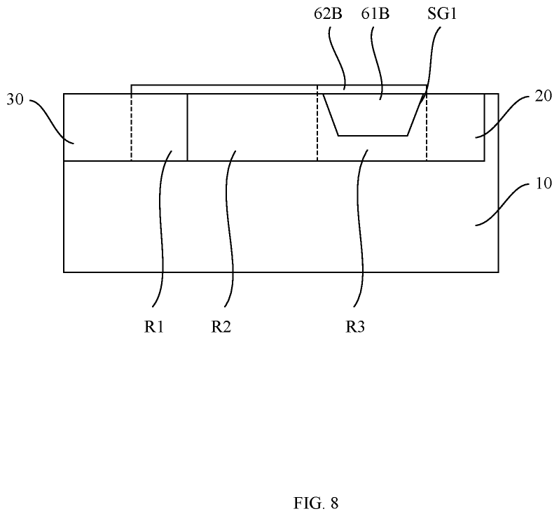

At S143B, insulation layer 62B can be formed and partially etched. For example, insulation layer 62B can be formed on substrate 10 to cover a part surface of well region 20 and a part surface of body region 30. For example, the method for forming insulation layer 62B can be the same as the method for forming insulation layer 61B. Then, insulation layer 62B may be etched by ICP-RIE or wet etching, and insulation layer 62B as shown in FIG. 8 may remain. It should be noted that steps S15-S17 of FIG. 4 are applicable to isolation structures 60A and 60B, and the steps S15-S17 performed in isolation structure 60B may be the same as those performed in isolation structure 60A. Steps S15-S17 will be described with isolation structure 60A as an example.

Referring back to FIG. 4, at S15, gate structure 70 may be formed on isolation structure 60A. For example, a polysilicon layer can be formed on isolation structure 60A and substrate 10 by sputtering, vapor deposition, or chemical vapor deposition methods, followed by partially etching of the polysilicon layer. This may leave the polysilicon layer as shown in FIG. 6D remaining to serve as the gate structure 70, and a part of oxide layer 61A located on drift region R3 can be exposed.

At S16, an ion implantation process may be performed on a first part of gate structure 70 to form gate region 71 of the first doped type, where gate region 71 can at least be located above body region 30. For example, as shown in FIG. 6E, gate structure 70 at least located above channel region R1 may be configured as the first part of gate structure 70. By ion implantation, gate region 71 of the first doped type can be formed in the first part of gate structure 70. In other examples, drain region 50, source region 40 and gate region 71 may be formed synchronously.

At S17, an ion implantation process can be performed on a second part of gate structure 70 to form gate region 72 of the second doped type, where gate region 72 is located above well region 20. For example, as shown in FIG. 6F, gate structure 70 located above accumulation region R2 and drift region R3 may be configured as second part of gate structure 70. By ion implantation, gate region 72 of the second doped type can be formed in the second part of gate structure 70.

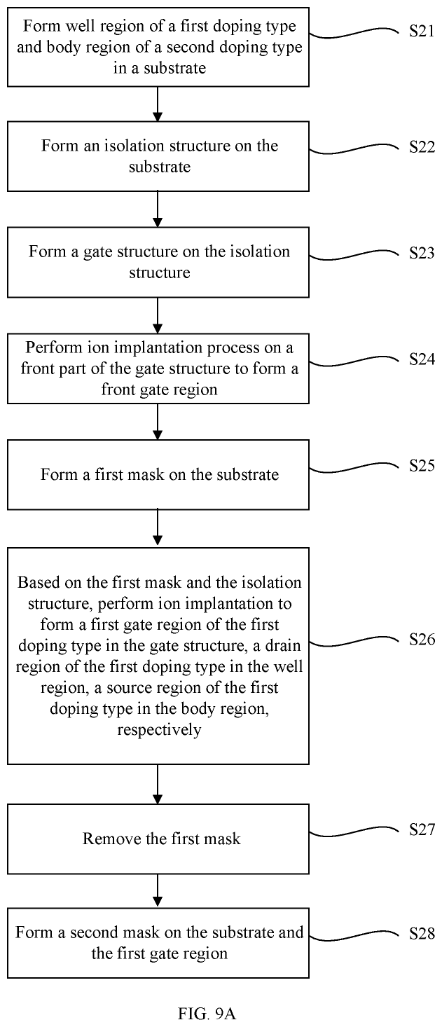

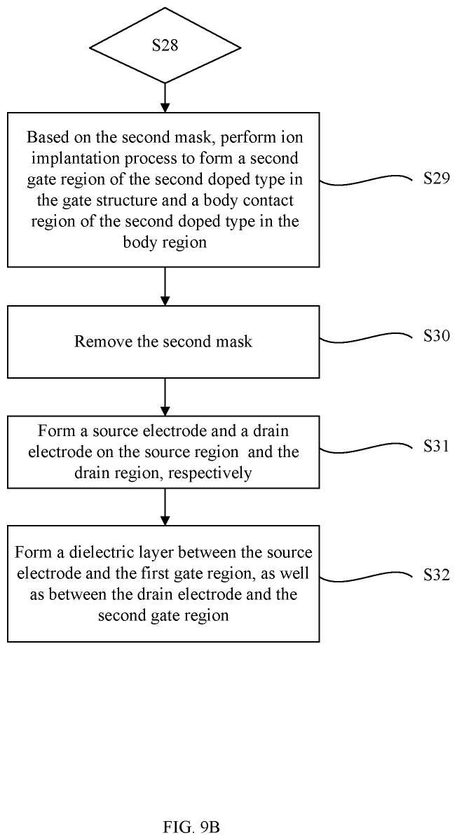

Referring now to FIGS. 9A and 9B, shown are flow diagrams of an example manufacturing method of the second example isolation structure, in accordance with embodiments of the present invention. In this particular example, the manufacturing method of semiconductor devices can include steps S21-S32, where steps S21-S23 are the same as steps S11, S14, and S15 shown in FIG. 4. The following examples illustrate the manufacturing method of the semiconductor devices shown in FIGS. 9A and 9B to manufacture the semiconductor devices shown in FIG. 3.

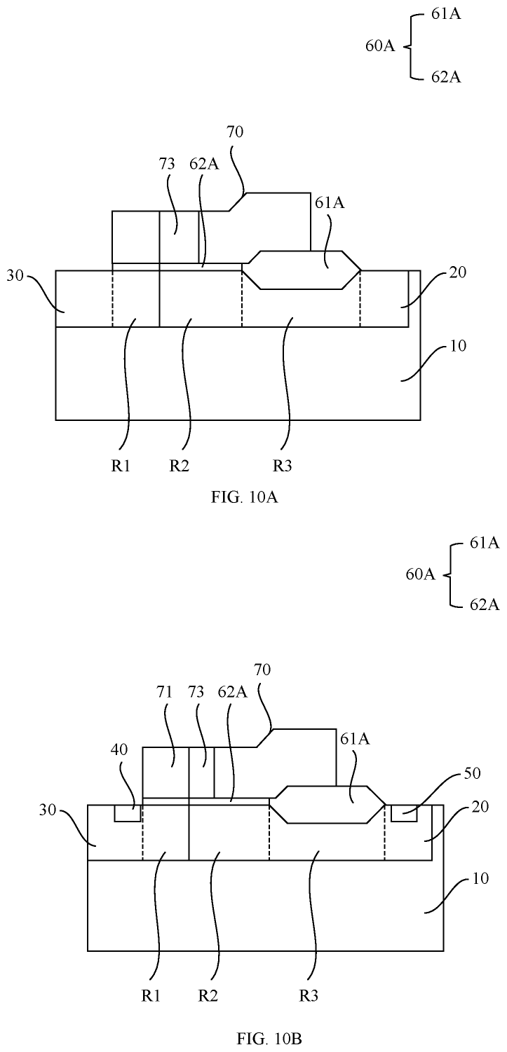

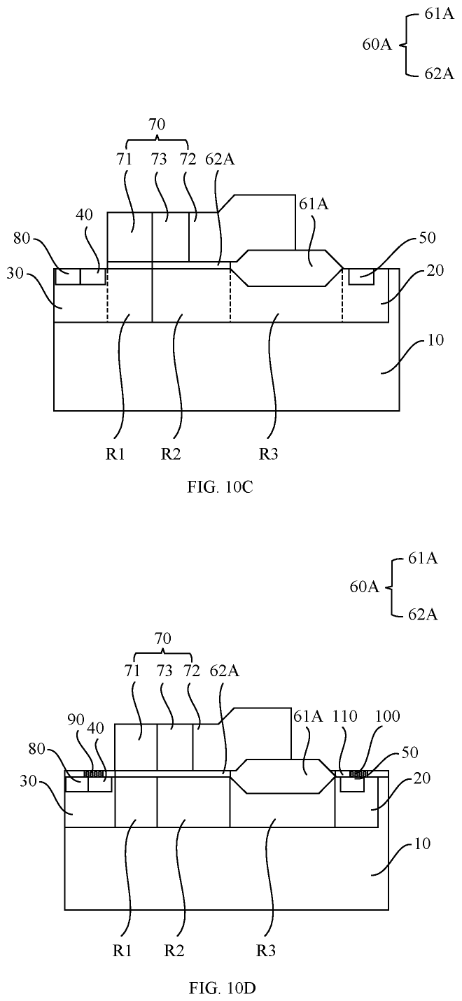

At S24, an ion implantation process may be performed on the front part of gate structure 70 to form front gate region 73. For example, as shown in FIG. 10A, gate structure 70 located on accumulation region R2 (e.g., gate structure 70 on well region 20) can be configured as the front part of gate structure 70. By the ion implantation process, front gate region 73 of the first doping type or front gate region 73 of the second doping type may be formed in the front part of gate structure 70.

Steps S25-S32 will be described using front gate region 73 of the first doping type as an example. At S25, a first mask can be formed on substrate 10. In one example, the first mask may be formed on substrate 10 by a spinning coating method. The first mask may at least cover one part of body region 30 and expose the other part of body region 30, gate structure 70, a part of oxide layer 61A, and a part of well region 20. Further, the first mask may cover the edge of body region 30 and expose body region 30 near gate structure 70, oxide layer 61A located on the drift region R3, and the edge of well region 20.

In another example, a first mask can be formed on substrate 10 and gate structure 70 by the spinning coating method. The first mask may cover a part of body region 30 and a part of gate structure 70, and expose a part of body region 30, a part of gate structure 70, a part of oxide layer 61A, and a part of well region 20. Further, the first mask may cover the edge of body region 30 and gate structure 70 located above accumulation region R2 and drift region R3, and expose body region 30 near gate structure 70, gate structure 70 located on channel region R1 and accumulation region R2, oxide layer 61A located on drift region R3, and the edge of well region 20.

At S26, based on the first mask and isolation structure 60A, ion implantation can be performed to form gate region 71 of the first doping type in gate structure 70, drain region 50 of the first doping type in well region 20, and source region 40 of the first doping type in body region 30, respectively. For example, based on the first mask and isolation structure 60A, ion implantation may be performed on body region 30 near gate structure 70, gate structure 70 located above channel region R1 and accumulation region R2, and the edge of well region 20 to form source region 40 of the first doped type in body region 30, gate region 71 of the first doped type in gate structure 70, and drain region 50 of the first doped type in well region 20, respectively.

At S27, the first mask can be removed. For example, after the step of removing the first mask, gate region 71, drain region 50, and source region 40 may be formed as shown in FIG. 10B. At S28, a second mask can be formed on substrate 10 and gate region 71. For example, the second mask may be formed on gate structure 70 by the spinning coating method. The second mask may cover gate region 71, front gate region 73, drain region 50, and source region 40, and may expose a part of body region 30, and gate structure 70 located on accumulation region R2 and drift region R3.

At S29, based on the second mask, an ion implantation process can be performed to form gate region 72 of the second doped type in gate structure 70 and body contact region 80 of the second doped type in body region 30. For example, based on the second mask, an ion implantation process may be performed on body region 30 near source region 40 and gate structure 70 located on accumulation region R2 and drift region R3 to form gate region 72 of the second doped type in gate structure 70 and body contact region 80 of the second doped type in body region 30.

At S30, the second mask may be removed. For example, after removing the second mask, gate region 72, and body contact region 80 can be formed as shown in FIG. 10C. Front gate region 73 located between gate region 71 and gate region 72 can be formed by an ion implantation process after the step of forming the first gate region or after the step of forming the second gate region, where the doping concentration of front gate region 73 is lighter than the doping concentration of the first gate region and the doping concentration of the second gate region.

At S31, source electrode 90 and drain electrode 100 may be formed on source region 40 and drain region 50, respectively. For example, with the assistance of a metal mask, source electrode 90 and drain electrode 100 as shown in FIG. 10D can be formed on source region 40 and drain region 50. For example, source region 40 and drain region 50 may be exposed by the metal mask, and the methods for forming source electrode 90 and drain electrode 100 can be sputtering, vapor deposition, or chemical vapor deposition.

At S32, dielectric layer 110 can be formed between source electrode 90 and gate region 71, as well as between drain electrode 100 and gate region 72. For example, dielectric layer 110 may be formed by CVD on substrate 10, oxide layer 61A not covered by gate structure 70, and gate structure 70. Dielectric layer 110 can be partially etched to remove oxide layer 61A not covered by gate structure 70, and dielectric layer 110 on gate structure 70, and to expose source electrode 90 and drain electrode 100. Dielectric layer 110 as shown in FIG. 10D may then remain.

In this way, by configuring the first gate region and the second gate region with two opposite doping types, the gate structure can be promoted to participate in depletion to form a depletion layer, the surface electric field and drain-gate capacitance of the accumulation region may be reduced, and thereby the influence of hot carrier injection effect can be reduced. Therefore, the current of the semiconductor device in this application may remain stable with over time, and thereby the reliability of the semiconductor device can be improved and the switching loss of the semiconductor device optimized.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A semiconductor device, comprising:
a) a substrate;
b) a well region located in the substrate and having a first doping type;
c) a body region located in the substrate and having a second doping type that is opposite to the first doping type;
d) a source region located in the body region and having the first doping type;
e) a drain region located in the well region and having the first doping type;
f) an isolation structure located on the substrate and between the drain region and the source region; and
g) a gate structure located on the isolation structure and comprising a first gate region and a second gate region, wherein the first gate region is of the first doping type, and the second gate region is of the second doping type.

2. The semiconductor device of claim 1, wherein the first gate region is at least located on the isolation structure above the body region, and the second gate region is at least located on the isolation structure above a part of the well region.

3. The semiconductor device of claim 1, further comprising a body contact region that is located in the body region and adjacent to the source region, wherein the body contact region is of the second doping type.

4. The semiconductor device of claim 1, wherein:
a) the isolation structure comprises a first oxide layer and a second oxide layer;
b) the first oxide layer is located on an upper surface of the well region and a first side of the first oxide layer is adjacent to the drain region;
c) the first oxide layer protrudes relative to a top surface of the substrate and extends towards the well region; and
d) the second oxide layer is located on a second side of the first oxide layer and at least extends to the source region.

5. The semiconductor device of claim 1, wherein the isolation structure comprises a shallow trench filled with a first insulation layer, and a second insulation layer, wherein the shallow trench is located in the well region, and the second insulation layer is at least located between the shallow trench and the source region.

6. The semiconductor device of claim 4, wherein the substrate comprises a channel region, an accumulation region, and a drift region that are located between the source region and the drain region, wherein the channel region is located in the body region below the gate structure, the drift region is located in the well region below the first oxide layer or the shallow trench, and the accumulation region is located between the channel region and the drift region.

7. The semiconductor device of claim 6, wherein the first gate region is located on the channel region, and the second gate region is located on the drift region and the accumulation region.

8. The semiconductor device of claim 6, wherein the first gate region is located on the channel region and a first part of the accumulation region, and the second gate region is located on the drift region and a second part of the accumulation region.

9. The semiconductor device of claim 6, wherein the gate structure further comprises a front gate region that is located between the first gate region and the second gate region and is located on the accumulation region, wherein the front gate region is of the first doping type and/or the second doping type.

10. The semiconductor device of claim 9, wherein the doping concentration of the front gate region is lower than that of the first gate region and the second gate region.

11. A method of making semiconductor devices, the method comprising:
a) forming a well region of a first doping type, and a body region of a second doping type in substrate, wherein the second doping type is opposite to the first doping type;
b) forming a drain region of the first doping type in the well region;
c) forming a source region of the first doping type in the body region;
d) forming an isolation structure on the substrate, the isolation structure being located between the drain region and the source region;
e) forming a gate structure on the isolation structure; and
f) performing ion implantation on a first part of the gate structure to form a first gate region of the first doped type, and performing ion implantation on a second part of the gate structure to form a second gate region of the second doped type.

12. The method of claim 11, wherein the drain region, the source region, and the first gate region are formed synchronously.

13. The method of claim 11, further comprising forming a body contact region of the second doping type in the body region, wherein the body contact region and the second gate region are formed synchronously.

14. The method of claim 11, wherein the first gate region is at least located on the isolation structure above the body region, and the second gate region is at least located on the isolation structure above a part of the well region.

15. The method of claim 11, wherein the step of forming the drain region, the source region, and the first gate region synchronously, comprises:
a) forming a first mask on the substrate, wherein the first mask at least partially covers the body region;
b) forming, using the first mask and the isolation structure as masks, the first gate region of the first doping type in the gate structure, the drain region of the first doping type in the well region, the source region of the first doping type in the body region by ion implantation; and
c) removing the first mask.

16. The method of claim 15, wherein the step of forming the body contact region and the second gate region synchronously, comprises:
a) forming a second mask on the substrate and the first gate region, wherein the second mask at least covers the drain region and the source region, and exposes a part of the body region;
b) forming, using the second mask as a mask, the second gate region of the second doping type in the gate structure, and the body contact region of the second doping type in the body region; and
c) removing the second mask.

17. The method of claim 11, further comprising performing ion implantation on a front part of the gate structure to form a front gate region, wherein the front gate region is located between the first gate region and second gate region.
